(19) United States
(12) Patent Application Publication
(10) Pub. No.: US 2021/0175912 A1
(43) Pub. Date: Jun. 10, 2021

(54) COMMUNICATION APPRATUS AND DECODING METHOD

(71) Applicant: NEC Corporation, Minato-ku, Tokyo (JP)

(72) Inventor: Soubhik DEB, Tokyo (JP)

(73) Assignee: NEC Corporation, Minato-ku, Tokyo (JP)

(21) Appl. No.: 17/267,967

(22) PCT Filed: Aug. 21, 2018
(86) PCT No.: PCT/JP2018/030852

§ 371 Date: Feb. 11, 2021

(51) Int. Cl. H04B 1/04; H03M 3/00; H04L 25/03

(52) U.S. Cl. CPC H04B 1/04; H04L 25/03; H03M 3/50

(57) ABSTRACT

A communication apparatus (50) includes a path splitting unit configured to split an existing path into two paths, with one path being formed by appending 1 to the existing path and, the other path being formed by appending −1 to the existing path; a path metric sort unit (53) configured to sort the paths in the ascending order of their path metric values; and a path pruning unit (54) configured to choose L (L is an integer more than 1) paths which have lower path metric values; a select path unit (55) configured to select a path with lowest path metric among all available paths at the end of all the baseband samples and the selected path serving as the output bit sequence.

### TECHNICAL FIELD

The present disclosure relates to a communication apparatus and a decoding method.

### BACKGROUND ART

There has been a significant research effort made in the area of radio-frequency (RF) transceivers using novel hardware implementations that rely on full digitalization of the RF data path. The motivation for this research is to bring the digital-to-analog interface in an RF transmitter as close as possible to the antenna. This is because designing a digital part using digital CMOS circuits is more cost effective and easily reconfigurable as compared to designing RF and analog parts. State-of-the-art all-digital transmitters typically use baseband DSM (Delta-Sigma Modulator) to digitally upconvert the baseband signals to RF signals. Baseband pulse modulation enables the use of field-programmable gate array (FPGA) devices for implementing a radio-frequency device, providing additional flexibility due to the FPGA inherent reconfigurability. FPGA's logic capacity, resource diversity, and dedicated high-speed I/O transceivers can be used in the development of agile all-digital transmitters.

### CITATION LIST

### Patent Literature

PTL 1: Erwin Janssen, and Derk Reefman, Generating Bit-streams with higher compression gains, US 2007/0018857 A1

### Non Patent Literature

NPTL 1: S. R. Norsworthy, R. Schreier, and G. C. Temes, Delta-Sigma Data Converters—Theory, Design and Simulation. IEEE Circuits and Systems Society, 1996.
NPTL 2: Ido Tal, and Alexander Vardy, List Decoding of Polar Codes, IEEE Transactions of Information Theory, Volume 61, Issue 5, 2015.

### SUMMARY OF INVENTION

### Technical Problem

FIG. 1 illustrates an example of DSM 10 for an all-digital transmitter. The objective of using DSM is to generate a high-speed 1-bit signal that contains information in the transmit band defined by the targeted standard. One of the potential advantages of a 1-bit coded digital RF signal is the ability to use class-S switched power amplifiers having a very high efficiency. FIG. 2 depicts output of a typical 1-bit 1^{st} order DSM. The comparator 11 for the 1-bit 1^{st} order DSM works as:

$$p ( n ) = \{ \begin{matrix}- 1 , & if u ( n ) < 0 \\ 1 , & if u ( n ) \geq 0\end{matrix}$$

FIG. 3 illustrates an example bit sequence of the output of DSM at some n-th baseband sample x(n).

FIG. 3 illustrates output of a 1-bit 1^{st} order DSM where the quantizer is replaced by addition of error function, e(n). This error function is defined as:

e(n)=p(n)−u(n)

The transfer function of a typical DSM in z-domain is given by:

P(z)=STF(z)X(z)+NTF(z)E(z)

where X(z), P(z) and E(z) are the transfer functions of x(n), p(n) and e(n), respectively. The main asset of the DSM is the possibility of being able to move quantization noise e(n) outside the band of interest, which is called noise shaping. This noise shaping is accomplished by designing appropriate noise shaping function NTF(z). For example, in 1^{st} order DSM, NTF(z)=1−z⁻¹. The performance of a DSM mainly depends on its noise-shaping filter order and its oversampling ratio (OSR), which is the ratio of the sampling frequency to twice the signal bandwidth. For more details on DSM, please refer to NPTL 1.

In DSM 10 shown in FIG. 1, each bit in the 1-bit coded digital RF signal output from DSM 10 is evaluated based on instantaneous values of u(n). This is visible from the comparator equation as shown below:

$$p ( n ) = \{ \begin{matrix}- 1 , & if u ( n ) < 0 \\ 1 , & if u ( n ) \geq 0\end{matrix}$$

This is a greedy approach whereby the focus is on minimization of quantization error e(n) in n-th baseband sample only. However, this greedy approach doesn't guarantee the following objective:

$$min {\sum }_{i = 1}^{N} e ( i ) \qquad ( 1 )$$

where N is the total number of samples of baseband signal x(n). The expression (1) is the summation of all quantization noise across all N samples of baseband signal x(n). The presence of quantization noise leads to a higher noise floor and bad ACLR (Adjacent Channel Leakage Ratio) performance.

The DSM mentioned in NPTL 1, as shown in FIG. 1, tries to predict the bit sequence that best quantizes the input baseband signal x(n). The DSM uses just the instantaneous input x(n) for this prediction purpose. A correct prediction will result in minimization of the feedback error f(n). A bad prediction will result in accumulation of more and more prediction error. As the input baseband signal x(n) is not known apriori, the output bit stream p(n) may not always be the best possible output.

In view of the above, one of the objects to be attained by embodiments disclosed herein is to provide an apparatus and a method that contribute to decrease the quantization noise. It should be noted that this object is merely one of the objects to be attained by the embodiments disclosed herein. Other objects or problems and novel features will be apparent from the following description and the accompanying drawings.

### Solution to Problem

In a first aspect, a communication apparatus includes: a path metric update unit configured to update the path metric of each path at each iteration; a path creator configured to split an existing path into two paths, with one path formed by appending 1 to existing path and, another path formed by appending −1 to the existing path; a path metric sort unit configured to sort the paths in the ascending order of their path metric values; a path pruning unit configured to choose those L paths which have lower path metric values; a select path unit configured to choose a path with the lowest path metric among all available paths at the end of all the baseband samples and the selected path serving as the output bit sequence; a feedback selector configured to select the feedback corresponding to the feedback associated with paths selected in path pruning unit; and a computation unit configured to process the feedback from the feedback selector and the input baseband signal, and to give feedback for next time instant as the output.

In a second aspect, a decoding method comprising: updating a path metric of each path at each iteration; splitting an existing path into two paths, with one path being formed by appending 1 to the existing path and, the other path being formed by appending −1 to the existing path; sorting the paths in the ascending order of their path metric values; choosing L (L is an integer more than 1) paths which have lower path metric values; selecting a path with lowest path metric among all available paths at the end of all the baseband samples and the selected path serving as the output bit sequence; selecting the feedback corresponding to the feedback associated with paths selected by path pruning; processing the selected feedback and the input baseband signal to give feedback for next time instant as the output.

### Advantageous Effects of Invention

According to the above-described aspects, it is possible to provide a communication apparatus and a decoding method that contribute to decrease the quantization noise.

### BRIEF DESCRIPTION OF DRAWINGS

FIG. 1 is a block diagram schematically representing a basic configuration of a communication apparatus.

FIG. 2 schematically illustrates a timing diagram for a path in 1-bit DSM.

FIG. 3 illustrates the mechanism behind a path splitting procedure.

FIG. 4 illustrates the mechanism behind the path splitting procedure.

FIG. 5 schematically illustrates a configuration of the communication apparatus according to the first exemplary embodiment.

FIG. 6 illustrates the timing diagram for the output of the proposed first exemplary embodiment.

FIG. 7 schematically illustrates a configuration of the communication apparatus according to the second exemplary embodiment.

### DESCRIPTION OF EMBODIMENTS

Exemplary embodiments of present disclosure will be described below with reference to the drawings. In the drawings, the same elements are denoted by the same reference numerals, and thus repeated descriptions are omitted as needed.

In order to mitigate the above problem, we incorporate the features of List Decoding, as provided in reference NPTL 2. This will help us to choose the output p(n) that minimizes sum of the all quantization error across all samples of input baseband signal x(n) as stated in Equation (1). Under List decoding, after n-th sample, the system maintains candidates of bit sequences of length n that will closely approximate the complete bit stream that minimizes Equation (1).

### First Exemplary Embodiment

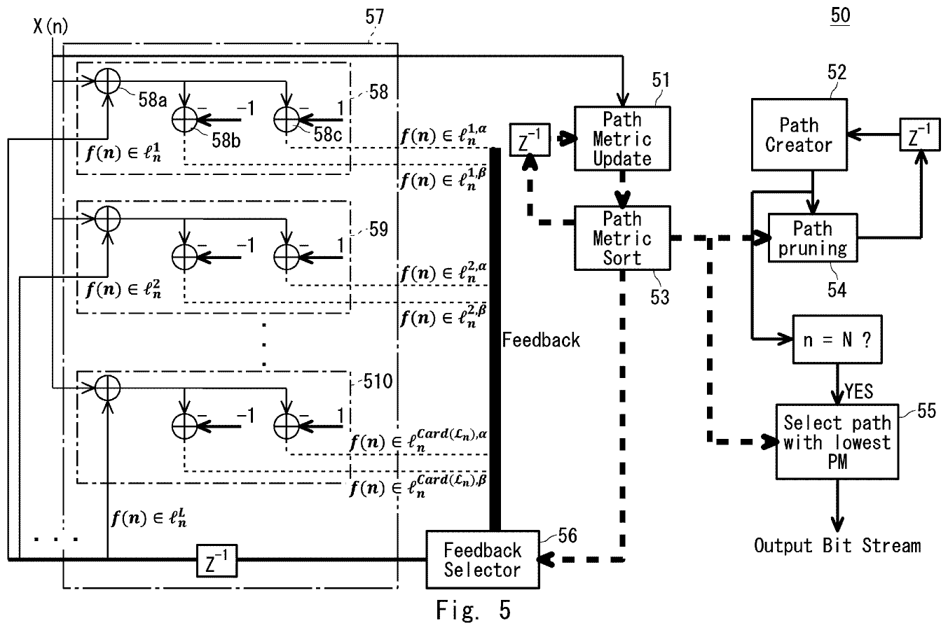

A communication system apparatus according to a first exemplary embodiment will be described. FIG. 5 is a block diagram schematically illustrating a basic configuration of the communication apparatus 50 according to the first exemplary embodiment. The communication apparatus 50 includes a path creator 52, a path metric update unit 51, a path metric sort unit 53, a path pruning unit 54, a select path unit 55, a feedback selector 56, and a computation unit 57.

Definition of Path:

An n-dimensional path lₙ is the sequence of output of 1-bit DSM till n-th sample such that

[symbol]

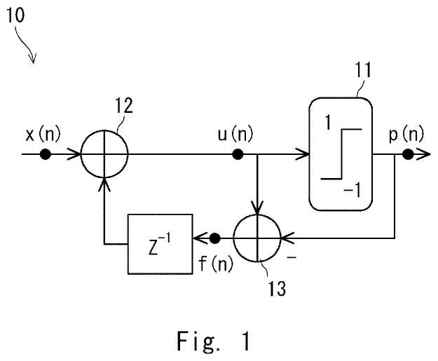

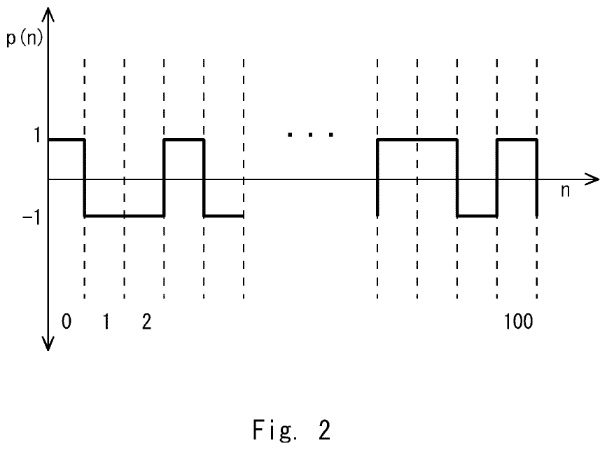

ₙ={p(0),p(1), . . . ,P(n)}

where p(0), p(1), . . . p(n) are the output of the 1-bit DSM as shown in FIG. 1 at time 0, 1, . . . , n, respectively, when the input baseband samples are x(0), x(1), . . . , x(n), respectively. p(n) is an output of the comparator 11 illustrated in FIG. 1 and indicates “1” or “−1”. The comparator 11 compares u(n) with a threshold, and output a comparison result as p(n). The input signal x(n) is input to the adder 12. The adder 12 adds x(n) to f(n−1), and outputs it as u(n). The adder 13 adds u(n) and −p(n), and output it as f(n). For example, in FIG. 2, we provide a snapshot of a path in the 1-bit DSM at n=100. The path can be written as follows:

[symbol]

₁₀₀={1,−1,−1,1,−1, . . . ,1,1,−1,1}

Path Metric (PM):

We define ε(n)=x(n)−p(n).

Consider a function PM( [symbol] ₀) initialization as follows

PM( [symbol] ₀)

PM( [symbol] ₁)=|ε(1)|²

PM( [symbol] ₙ₊₁)=PM( [symbol] ₙ)+|ε(n+1)|²

where, [symbol] ₁={p(1)}

[symbol]

ₙ={p(0),p(1), . . . ,p(n)}

lₙ₊₁={p(0),p(1), . . . ,p(n+1)}

Note that path [symbol] ₙ₊₁ at time (n+1) is obtained by appending, p(n+1) to the path [symbol] ₙ. Thus, PM(⋅) is iteratively updated with value of PM( [symbol] ₙ₊₁) obtained by adding square of ε(n+1) to the path metric of the path [symbol] ₙ, that is, PM( [symbol] ₙ).

Some notations are as follows:

[symbol] ₙ₋₁: collection of all paths at the end of processing in (n−1)-th time instance

[symbol] ₙ: collection of all paths at the end of processing in n-th time instance

Card( [symbol] ₙ): cardinality of the collection [symbol] ₙ

L: maximum number of paths that is to be stored at the end of processing in each time instant due to FPGA memory constraint.

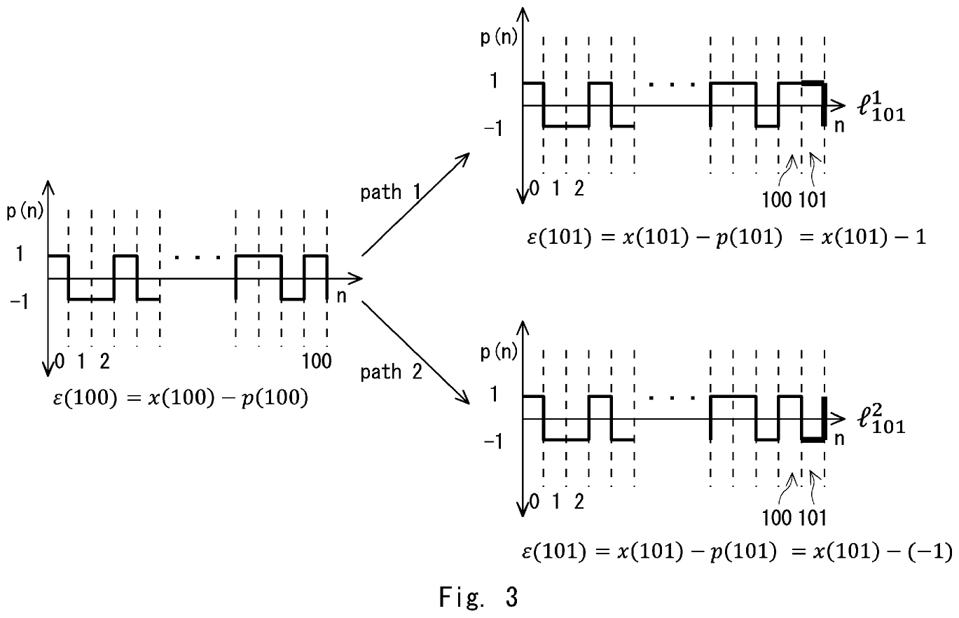

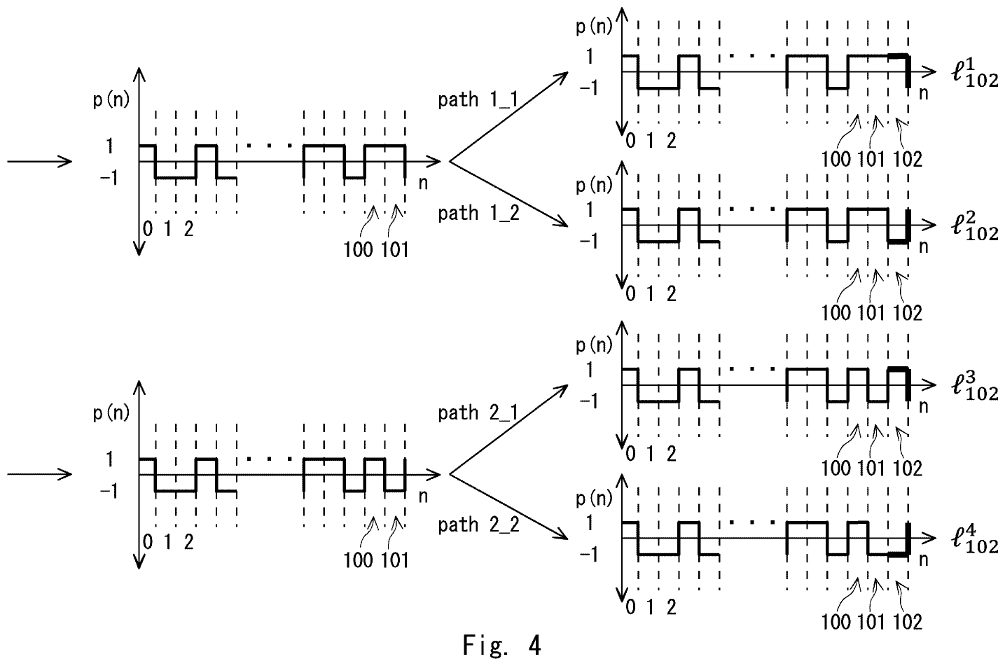

At n-th instant, the path creator 52 receives as input the list of all paths that were selected after path pruning in previous iteration, i.e, [symbol] ₙ₋₁, from path pruning unit 54. For each path [symbol] ₙ₋₁ϵ [symbol] ₙ₋₁, the path creator 52 creates two paths [symbol] ₙ^{α} and [symbol] ₙ^{β}, such that [symbol] ₙ^{α}={ [symbol] ₙ₋₁,−1} and [symbol] ₙ^{β}={ [symbol] ₙ₋₁,1}. Now, [symbol] ₙ^{α}, [symbol] ₙ^{β}ϵ [symbol] ₙ. Note that Card( [symbol] ₙ)=2L. An example of path splitting is given in FIG. 3 and FIG. 4 for n=101 and n=102, respectively. Note that [symbol] ₁₀₁¹={ [symbol] ₁₀₀,1} and [symbol] ₁₀₁²={ [symbol] ₁₀₀,−1}. Also, [symbol] ₁₀₂¹={ [symbol] ₁₀₁¹,1}, [symbol] ₁₀₂²={ [symbol] ₁₀₁¹,−1}, [symbol] ₁₀₂³={ [symbol] ₁₀₁¹,1} and [symbol] ₁₀₂⁴={ [symbol] ₁₀₁²,−1}.

At a-th instant, the path metric update unit 51 receives as input the list of p metrics of all paths that were selected after path pruning in previous iteration. i.e., [symbol] ₙ₋₁. More specifically, the input to path metric update unit 51 at time n is {PM( [symbol] ₙ₋₁¹), PM( [symbol] ₙ₋₁²), . . . , PM( [symbol] ₙ₋₁^{Card(} [symbol] ^{_{n−1}}⁾)}. In n-th instant, the path metric update unit 51 updates the path metrics of the paths [symbol] ₙ^{α} and [symbol] ₙ^{β} as:

$$\begin{matrix}PM ( {𝓁}_{n}^{α} ) = PM ( {𝓁}_{n - 1} ) + {\vert ɛ ( n ) \vert}^{2} & = PM ( {𝓁}_{n - 1} ) + {\vert \begin{matrix}x ( n ) & + 1\end{matrix} \vert}^{2} \\ PM ( {𝓁}_{n}^{β} ) = PM ( {𝓁}_{n - 1} ) + {\vert ɛ ( n ) \vert}^{2} & = PM ( {𝓁}_{n - 1} ) + {\vert \begin{matrix}x ( n ) & - 1\end{matrix} \vert}^{2}\end{matrix}$$

$$where$$

$${𝓁}_{n}^{α} = \{ {𝓁}_{n - 1} , - 1 \} and {𝓁}_{n}^{β} = \{ {𝓁}_{n - 1} , 1 \} .$$

At n-th instar the path metric sort unit 53 sorts the paths in [symbol] ₙ in an ascending order as per the math metric. That is, after sorting, if [symbol] ₙ={ [symbol] ₙ¹, [symbol] ₙ², . . . , [symbol] }, then, PM( [symbol] ₙ¹)≤PM( [symbol] ₙ²)≤ . . . PM( [symbol] ). The path metric sort unit 53 outputs the result of sort to the path pruning unit 54. Because of PPG A memory constraint, the path pruning unit 54 selects L paths identified as [symbol] ₙ¹, [symbol] ₙ², . . . , [symbol] ₙ^{L}, where PM( [symbol] ₙ¹)≤PM( [symbol] ₙ²)≤ . . . PM( [symbol] ₙ^{L}) The path pruning unit 54 deletes the rest of the L paths [symbol] ₙ^{L+1}, [symbol] ₙ^{L+2}, . . . , [symbol] . The path metric values of the L selected paths in the n-th time instant, that is, PM( [symbol] ₙ¹), PM( [symbol] ₙ²), . . . , PM( [symbol] ₙ^{L}), are used in the next time instant (n+1) at the path metric update unit 51. The path metric values of the delete L paths are PM( [symbol] ₙ^{L+1}) to PM( [symbol] ).

At n-th time instant, path pruning unit 54 selects unit L paths out of 2L paths for pruning. This selection of L paths is done using the result of sorting at the path metric sort unit 53. The path metric sort unit 53 informs the path pruning unit 54 of the L paths that have been of selected. That is, path pruning unit 54 selects the paths identified as [symbol] ₙ¹, [symbol] ₙ², . . . , [symbol] ₙ^{L} according to the result of sorting in path metric sort unit 53. The rest of the paths are deleted. The selected L paths, [symbol] ₙ¹, Lₙ², . . . , [symbol] ₙ^{L}, are sent hack to the path creator 52 so as to be used in the next time instant (n+1).

As described above, the Path pruning unit 54 outputs L (L is an integer more than 1) paths to the path creators 52. Then, the Path creator 52 creates 2L paths by splitting each of the L paths into two paths, and thus functions as a path splitting unit. The Path Metric updates unit 51 updates the path metrics of the 2L paths. The Path metric sort unit 53 arranges the 2L paths in ascending order of the path metric. The path pruning unit 54 selects new L paths based on the path metric values. That is, the path pruning unit 54 chooses the L paths having the lower path metric values out of 2L paths. The Path pruning unit 54 deletes L paths having the higher path metric values. That is, the path pruning unit 54 retains half of the created paths and deletes the other half of the created paths.

The path metric sort unit 53 and the path pruning unit 54 is different from the implementation in PTL 1. In PTL 1, at each time instant, path metrics of all the paths with the same newest L bits are compared. It is obvious that communication apparatus 50 can obtain a multiple groups of paths. In each group, the L newest bits are the same. For path pruning, in each group, the paths with lower path metric are retained and the rest are thrown away. This process gives rise to suboptimal search for the path with the minimum path metric. However, Sort and Pruning procedure described in this embodiment is global in its approach.

At n-th instant, the input to the feedback selector 56 are feedback f(n) in each of the paths [symbol] ₙ^{1,α}, [symbol] ₙ^{1,β}, [symbol] ₙ^{2,α}, [symbol] ₙ^{2,β}, . . . , [symbol] ^{α}, [symbol] ^{β}, where [symbol] ₙ^{1,α}={ [symbol] ₙ¹,1}, [symbol] ₙ^{1,β}={ [symbol] ₙ¹,−1}, [symbol] ₙ^{2,α}={ [symbol] ₙ²,1}, lₙ^{2,β}={ [symbol] ₙ²,−1}, . . . , [symbol] ^{α}={ [symbol] ,1}, [symbol] ^{β}={ [symbol] ,−1}. Using the result of sorting in the path metric sort unit 53, the feedback selector 56 selects those feedbacks 10) corresponding to the paths [symbol] ₙ¹, [symbol] ₙ², . . . , [symbol] ₙ^{L}. The feedbacks of the selected paths are used in the next time instant (n+1) in the computational unit 57.

At n-th instant, the computation unit 57 receive an input signal x(n) which is the n-th baseband sample of a baseband signal. The computation unit 57 include L sub-units 58 to 510. Each of the sub-units 58 to 510 includes three adders. For example, the sub-unit 58 includes the adders 58a to 58c. The adder 58a adds x(n) to f(n−1), and outputs it to the adders 58b and 58c. The adder 58b adds the output from adder 58a to “1”. The adder 58c adds the output from the adder 58a to “−1”.

The computational unit 57 is configured red to add the input signal x(n) and the feedback corresponding to the paths [symbol] ₙ₋₁¹, [symbol] ₙ₋₁², . . . , [symbol] ₙ₋₁^{L} obtained from the feedback selector 56 in previous time instant n−1. The computational unit 57 has L parallel sub-units with each sub-unit containing three adders. In each sub-unit, the baseband sample is added with the corresponding feedback to get the modified signal. After that, 1 and −1 is subtracted from the modified signal to obtain feedbacks fin) corresponding to the paths [symbol] ₙ^{1,α}, [symbol] ₙ^{1,β}, [symbol] ₙ^{2,α}, lₙ^{2,β}, . . . , [symbol] ^{α}, [symbol] ^{β}. The feedback corresponding to the above paths are then sent to feedback selector 56.

After the last sample of baseband signal, x(N) has been quantized at N-th time instant, the select path unit 55 selects the path with the lowest path metric.

To accomplish this, it takes as an input all paths obtained alter path splitting in the path creator 52, that is, [symbol] ₙ¹, [symbol] ₙ², . . . , [symbol] . Using the output of the path metric sort unit 53, the select path unit 55 selects the path with the lowest path metric value, that is, [symbol] ₙ¹, where PM( [symbol] ₙ¹)≤PM( [symbol] ₙ²)≤ . . . PM( [symbol] ) Now, the selected path [symbol] ₙ¹ is the output hit stream.

In comparison to PLT 1, our implementation of the path metric update unit 51, the path metric sort unit 53, the Path creator 52, the path pruning unit 54 and the associated components are disjoint from the feedback line. In FIG. 4 of PLT 1, the Path Sort and the path metric update is done along the main body. This disjoint nature adds flexibility to the DSM structure.

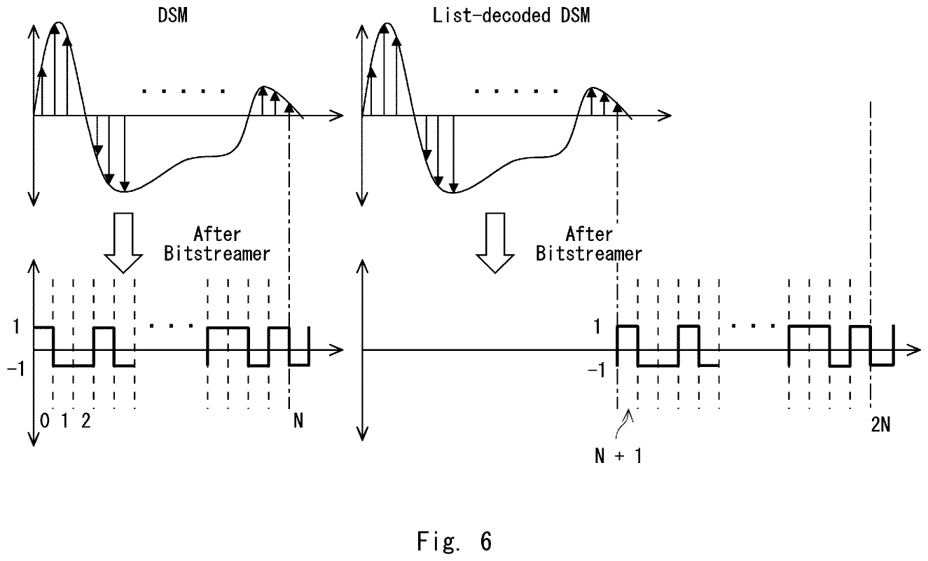

FIG. 6 illustrates the timing diagram of output of the select path unit 55. The timing diagram shows that there is a latency of N time instants in the output of the proposed list-decoded DSM. This is due to the fact that selection of a path with the lowest path metric is done at the select path unit 55 at the end of each N time instants.

Further, the communication apparatus 50 includes a bandpass filter through which the output bitstream (output bit sequence). Then, the communication apparatus 50 modulates the output bitstream with a carrier wave, and then transmit it as RF signal to a receiver. Therefore, it is possible to decrease the quantization noise and thus, effectively improve ACLR of an output bit stream and lower the noise floor.

### Second Exemplary Embodiment

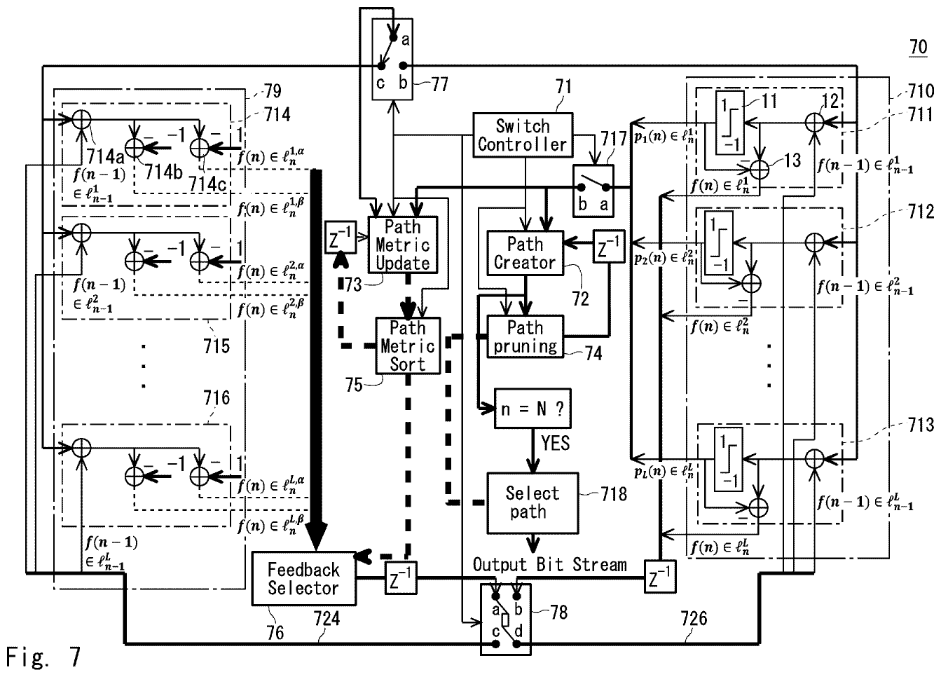

A communication system apparatus according to a second exemplary embodiment will be described. FIG. 7 is a block diagram schematically illustrating a basic configuration of the communication apparatus 70 according to the second exemplary embodiment. The communication apparatus 70 includes a path creator 72, a path metric update unit 73, a path metric sort unit 75, a path pruning unit 74, a select path unit 718, a feedback selector 76, a computation unit 710. The communication apparatus 70 includes a computation unit 79, switch 77, switch 78, switch 717 and switch controller 71. The path creator 72, the path metric update unit 73, the path metric sort unit 74, the path pruning unit 74 and the select path unit 718 correspond to the path creator 52, the path metric update unit 51, the path metric sort unit 53, the path pruning unit 54 and the select path unit 55, respectively, and the explanation thereof may be omitted.

The switch controller 71 chooses Mode 1 when it wants to use the computation unit 710 for computation of feedback (n). The switch controller 71 chooses Mode 2 when it wants to use the computation unit 79 for computation of feedback f(n). Applying list decoding at every time instant is cumbersome. So, an alternative is to define the switch controller 71 that selects the computation unit 710 most of the times. Note that computation unit 710 includes just many parallel units of conventional 1-bit DSM involving comparators. When the switch controller 71 selects the computation unit 710, the communication apparatus 70 does not execute the list decoding. The computation unit 79 is selected only intermittently. When the switch controller 71 selects the computation unit 79, the communication apparatus 70 executes the list decoding.

Suppose the switch controller 71 is in Mode 1 in n-th time instant. The feedback f(n−1) is sent to the computation unit 710 though a line 726. The computation unit 710 includes a plurality of sub-units 711 to 713. Each of the sub-units 711 to 713 includes a comparator 11 and an adder 12 like a structure shown in FIG. 1. In each of parallel sub-unit 711 to 713 in the computation unit 710, the adder 12 adds the input baseband signal x(n) to the feedback f(n−1) of the corresponding path.

For example, in computation unit 711 the adder 12 adds the feedback f(n−1)ϵ [symbol] ₙ₋₁¹ in to x(n). Subsequently; the computational unit 711 quantizes the output of the above summation using a comparator 11 that gives 1 or −1 as the output. This quantized output is then sent to the path creator 72 and the path metric update unit 73 via the switch 717. The feedback is generated by determining the quantization error f(n) which is sent to the switch 78.

Suppose the switch controller 71 is in Mode 2 in n-th time instant. The feedback f(n−1) is sent to the computation unit 79 though a line 724. The computation unit 79 includes a plurality of sub-units 714 to 716. Each of the sub-units 714 to 716 includes three adders like the sub-unit 58 as shown in FIG. 5. For example, the sub-unit 714 includes the adders 714a to 714c. In each parallel sub-unit 714 to 716 in computation unit 79, the adder adds the input baseband signal x(n) to the feedback f(n−1) of the corresponding path.

For example, in the computational unit 714, the adder 714a adds the feedback f(n−1)ϵ [symbol] ₙ₋₁¹ to x(n). Subsequently, the adders 714b and 714c add this above summation 1 and −1. Both of the feedbacks from each sub-unit are then sent to the feedback selector 76 so that the feedbacks corresponding to the paths that survived after the path pruning are selected. That is, for sub-unit 714, the feedbacks f(n)∈ [symbol] ₙ^{1,α} and f(n)∈ [symbol] ₙ^{1,β} are sent to the feedback selector 76.

At n-th instant, the path creator 72 receives as input the list of all paths that were selected after path pruning in the previous iteration, i.e, [symbol] ₙ₋₁. Also, the path creator 72 receives input from the switch controller 71. If the switch controller 71 chooses Mode 1, then the path creator 72 makes use of quantized input from the computation unit 710 to extend the paths in [symbol] ₙ₋₁. Elaborating further, suppose the feedback into the parallel sub-units for path [symbol] ₙ₋₁¹ in the computation unit 710 is f(n). Let the corresponding output after the comparator 11 be p₁(n). Then the path creator 72 will update path [symbol] ₙ₋₁¹ as [symbol] ₙ¹={ [symbol] ₙ₋₁¹,p₁(n)}. Similarly, the path creator 72 can update other paths [symbol] ₙ₋₁², . . . , [symbol] ₙ₋₁^{L} as [symbol] ₙ²={ [symbol] ₙ₋₁², p₂(n)}, . . . , [symbol] ₙ^{L}={ [symbol] ₙ₋₁^{L},p_{L}(n)}, respectively.

As described above, when the switch controller 71 selects Mode 1, the path creator 72 does not perform the path splitting.

On the other hand, if the switch controller 71 selects Mode 2, then Path creator 1 performs the path splitting.

Elaborating further, for each path [symbol] ₙ₋₁ϵ [symbol] ₙ₋₁, the path creator 72 creates two paths [symbol] ₙ^{α}α and [symbol] ₙ^{β}, such that [symbol] ₙ^{α}={ [symbol] ₙ₋₁,−1} and [symbol] ₙ^{β}={ [symbol] ₙ₋₁,1}. Now, [symbol] ₙ^{α}, [symbol] ₙ^{β}ϵ [symbol] ₙ. Note that Card( [symbol] ₙ)=2L. An example of the path splitting is given in FIG. 3 and FIG. 4 for n=101 and n=102, respectively. Note that [symbol] ₁₀₁¹={ [symbol] ₁₀₀,1} and [symbol] ₁₀₁²={ [symbol] ₁₀₀,−1}. Also, [symbol] ₁₀₂¹={ [symbol] ₁₀₁¹,1}, [symbol] ₁₀₂²={ [symbol] ₁₀₁¹,−1}, [symbol] ₁₀₂³={l₁₀₁²,1} [symbol] ₁₀₂⁴={ [symbol] ₁₀₁²,−1}.

At n-th instant, the path metric update unit 73 receives as input the n-th sample of the input baseband signal x(n).

At n-th instant, the path metric update unit 73 receives as input the list of path metrics of all paths that were selected after path pruning in the previous iteration, i.e. {PM( [symbol] ₙ₋₁¹), PM( [symbol] ₙ₋₁²), . . . , PM( [symbol] ₙ₋₁^{L})}. Elaborating further, if the switch controller 71 selects Mode 1, the path metric update unit 73 also receives the quantized values p₁(n), p₂(n), . . . , p_{L}(n). Using these quantized values, the path metric update unit 73 updates the path metrics of each path as follows:

$$\begin{matrix}PM ( {𝓁}_{n}^{1} ) = PM ( {𝓁}_{n - 1}^{1} ) + {\vert ɛ ( n ) \vert}^{2} & = PM ( {𝓁}_{n - 1}^{1} ) + {\vert x ( n ) - {p}_{1} ( n ) \vert}^{2} \\ PM ( {𝓁}_{n}^{2} ) = PM ( {𝓁}_{n - 1}^{2} ) + {\vert ɛ ( n ) \vert}^{2} & = PM ( {𝓁}_{n - 1}^{2} ) + {\vert x ( n ) - {p}_{2} ( n ) \vert}^{2} \\ ⋮ & \\ PM ( {𝓁}_{n}^{L} ) = PM ( {𝓁}_{n - 1}^{L} ) + {\vert ɛ ( n ) \vert}^{2} & = PM ( {𝓁}_{n - 1}^{L} ) + {\vert x ( n ) - {p}_{L} ( n ) \vert}^{2}\end{matrix}$$

$$where$$

$${𝓁}_{n}^{1} = \{ {𝓁}_{n - 1}^{2} , {p}_{1} ( n ) \} , {𝓁}_{n}^{2} = \{ {𝓁}_{n - 1}^{2} , {p}_{2} ( n ) \} , … , {𝓁}_{n}^{L} = \{ {𝓁}_{n - 1}^{L} , {p}_{L} ( n ) \} .$$

On the other hand, if the switch controller 71 selects Mode 2, then the path metric update 73 updates the path metric as follows.

At n-th instant, the path metric update unit 73 receives as input the list of path metrics of all paths that were selected after path pruning in previous iteration, i.e, [symbol] ₙ₋₁. More specifically, the input to path metric update unit 73 at time n is {PM( [symbol] ₙ₋₁¹), PM( [symbol] ₙ₋₁²), . . . , PM( [symbol] )}, In n-th instant, the path metric update unit 73 updates the path metrics of the paths [symbol] ₙ^{α} and [symbol] ₙ^{β} as:

$$\begin{matrix}PM ( {𝓁}_{n}^{α} ) = PM ( {𝓁}_{n - 1} ) + {\vert ɛ ( n ) \vert}^{2} & = PM ( {𝓁}_{n - 1} ) + {\vert \begin{matrix}x ( n ) & + 1\end{matrix} \vert}^{2} \\ PM ( {𝓁}_{n}^{β} ) = PM ( {𝓁}_{n - 1} ) + {\vert ɛ ( n ) \vert}^{2} & = PM ( {𝓁}_{n - 1} ) + {\vert \begin{matrix}x ( n ) & - 1\end{matrix} \vert}^{2}\end{matrix}$$

$$where$$

$${𝓁}_{n}^{α} = \{ {𝓁}_{n - 1} , - 1 \} and {𝓁}_{n}^{β} = \{ {𝓁}_{n - 1} , 1 \} .$$

At n-th instant, the path metric sort unit 75 receives as input the updated path metric of the paths in the path creator 72.

More specifically, if the switch controller 71 selects Mode 1, then the input to the path metric sort unit 75 is PM( [symbol] ₙ¹), PM( [symbol] ₙ²), . . . , PM( [symbol] ₙ^{L})}. In Mode 1, the path metric sort unit 75 just sends the path metric values PM( [symbol] ₙ¹), PM( [symbol] ₙ²), . . . , PM( [symbol] ₙ^{L}) as a feedback to the path metric update unit 73 so that these path metric values are used in the next time instant (n+1) at path metric update unit 73.

If the switch controller 71 selects Mode 2, then, at n-th instant, the path metric sort unit 75 sorts the paths in [symbol] ₙ in an ascending order as per the path metric. That is, after sorting, if [symbol] ₙ={ [symbol] ₙ¹, [symbol] ₙ², . . . , [symbol] }, then PM( [symbol] ₙ¹)≤PM( [symbol] ₙ²)≤ . . . PM( [symbol] ). Because of F PGA memory constraint, the path pruning unit 74 selects paths identified as [symbol] ₙ¹, [symbol] ₙ², . . . , [symbol] ₙ^{L}, where PM( [symbol] ₙ¹)≤PM( [symbol] ₙ²)≤ . . . M( [symbol] ₙ^{L}). The path pruning unit 74 deletes the rest of the paths [symbol] ₙ^{L+1}, [symbol] ₙ^{L+2}, . . . , [symbol] . The path metric values of the selected paths in n-th time instant, that is, PM( [symbol] ₙ¹), PM( [symbol] ₙ²), . . . , PM( [symbol] ₙ^{L}), are used in the next time instant (n+1) at the path metric update unit 73.

The path pruning 74 receives as input all paths from the path creator 72. At n-th instant, if switch controller 71 selects Mode 1, then the path pruning just send the incoming, paths [symbol] ₙ¹, [symbol] ₙ², . . . , lₙ^{L} back to the path creator 72 for use in next iteration (n+1).

When the switch controller 71 selects Mode 2, at n-th time instant, the path pruning unit 74 selects L paths out of 2L paths for the path pruning. This selection of L paths is done using the result of sorting at the path metric sort unit 75. The path metric sort unit 75 informs the path pruning unit 74 of the L paths that have been of selected.

That is, the path pruning unit 74 selects the paths identified as [symbol] ₙ¹, [symbol] ₙ², . . . , [symbol] ₙ^{L} according to the result of sorting in path metric sort unit 75. The rest of the paths are deleted. The selected L paths, [symbol] ₙ¹, [symbol] ₙ², . . . , [symbol] ₙ^{L}, are sent back to the path creator 72 so as to be used in the next time instant (n+1).

At n-th instant, the input to the feedback selector 76 is feedback f(n) in each of the paths [symbol] ₙ^{1,α}, [symbol] ₙ^{1,β}, [symbol] ₙ^{2,α}, [symbol] ₙ^{2,β}, . . . , [symbol] ^{α}, [symbol] ^{β}, where [symbol] ₙ^{1,α}={ [symbol] ₙ¹,1}, [symbol] ₙ^{1,β}={ [symbol] ₙ¹,−1}, [symbol] ₙ^{2,α}={ [symbol] ₙ²,1}, [symbol] ₙ^{2,β}={ [symbol] ₙ²,−1}, . . . , [symbol] ^{α}={ [symbol] ,1}, [symbol] ^{β}={ [symbol] ,−1}. Using the result of sorting in the path metric sort unit the feedback selector 76 selects those feedbacks tin) corresponding to the paths [symbol] ₙ¹, [symbol] ₙ², . . . , [symbol] ₙ^{L}. The feedbacks of the selected paths are used in the next time instant (n+1) in the computation unit 710 or the computation unit 79 depending on the mode selected by the switch controller 71 in time instant (n+1).

The switch 77 makes its decision at each time instant based on the input from the switch controller 71. The working of the switch 77 is explained as follows:
Suppose in n-th step, the switch controller 71 selects Mode 1 and thus the computation unit 710 is used for sending the input baseband signa x(n). In that case, the switch 77 configures to connect port a to port b.
Suppose in n-th step, the switch controller 71 selects Mode 2 and thus the computation unit 79 is used for sending the input baseband signal x(n). In that case, switch 77 configures to connect port a to port c.

The switch 78 makes its decision at each time instant based on the input from the switch controller 71. The working of the switch 78 is explained as follows:

Suppose in (n−1)-th step, computation unit 79 is used for computing the feed k f(n−1) and in n-th step, computation unit 710 is to be used for computing the feedback f(n). In that case, for obtaining the feedback f(n−1) for all the paths in [symbol] ₙ₋₁, the switch 78 configures to connect port a to port d.

Suppose in (n−1)-th step, the computation unit 710 is used for computing the feedback f(n−1) and in n-th step, the computation unit 710 is to be used for computing the feedback f(n). In that case, for obtaining the feedback f(n−1) for all the paths in [symbol] ₙ₋₁, the switch 78 configures to connect port b to port d.

Suppose in (n−1)-th step, the computation unit 710 is used for computing the feedback f(n−1) and in n-th step, the computation unit 79 is to be used for computing the feedback f(n). In that case, for obtaining the feedback f(n−1) for all the paths in [symbol] ₙ₋₁, the switch 78 configures to connect port b to port c.

Suppose in (n−1)-th step, computation unit 79 is used for computing the feedback f(n−1) and in n-th step, computation unit 79 is to be used for computing the feedback f(n). In that case, for obtaining the feedback f(n−1) for all the paths in [symbol] ₙ₋₁, the switch 78 configures to connect port a to port C.

After the last sample of baseband signal, x(N) has been quantized at N-th time instant, the block select path unit 718 selects the path with the lowest path metric.

To accomplish this, it takes as input all paths obtained after path splitting in path creator 72, that is, [symbol] ₙ¹, [symbol] ₙ², . . . , [symbol] . Using output of path metric sort 75, select the path with the lowest path metric value, that is, [symbol] ₙ¹, where PM( [symbol] ₙ¹)≤PM( [symbol] ₙ²)≤ . . . PM( [symbol] ). Now, the selected path [symbol] ₙ¹ is the output bit sequence.

In the exemplary embodiment described above, the phase control device has configured as a disk-like shape device. However, the shape of the phase control device is not limited to this. For example, the phase control device may be configured as a board-like shape device other than the disk-like shape device.

Some or all components and units as described in the above embodiments may be composed of hardware circuits or circuitry. Or. some or all components and units as described in the above embodiments may execute the processes by the software The communication apparatus in the above embodiments can execute one or more programs including a set of instructions to cause a computer to perform an algorithm described above with reference to the drawings. These programs may be stored in various types of non-transitory computer readable media and thereby supplied to computers. The non-transitory computer readable media includes various types of tangible storage media. Examples of the non-transitory computer readable media include a magnetic recording medium (such as a flexible disk, a magnetic tape, and a hard disk drive), a magneto-optic recording medium (such as a magneto-optic disk), a Compact Disc Read Only Memory (CD-ROM), CD-R, CD-R/W, and a semiconductor memory (such as a mask ROM, a Programmable ROM (PROM), an Erasable PROM (EPROM), a flash ROM, and a Random Access Memory (RAM)). These programs may be supplied to computers by using various types of transitory computer readable media. Examples of the transitory computer readable media include an electrical signal, an optical signal, and an electromagnetic wave. The transitory computer readable media can be used to supply programs to a computer through a wired communication line (e.g., electric wires and optical fibers) or a wireless communication line.

While the present disclosure has been described above with reference to exemplary embodiments, the present disclosure is not limited to the above exemplary embodiments. The configuration and details of the present disclosure can be modified in various ways which can be understood by those skilled in the art within the scope of the disclosure.

For example, the whole or part of the embodiments disclosed above can be described as, but not limited to, the following supplementary notes.

(Supplemental Note 1)

A communication apparatus comprising:

a path metric update unit configured to update a path metric of each path at each iteration;

a path splitting unit configured to split an existing path into two paths, with one path being formed by appending 1 to the existing path and, the other path being formed by appending −1 to the existing path;

a path metric sort unit configured to sort the paths in the ascending order of their path metric values;

a path pruning unit configured to choose L (L is an integer more than 1) paths which have lower path metric values;

a select path unit configured to select a path with lowest path metric among all available paths at the end of all the baseband samples and the selected path serving as the output bit sequence;

a feedback selector configured to select the feedback corresponding to the feedback associated with paths selected by the path pruning unit;

a computation unit configured to process the feedback from the feedback selector and the input baseband signal, and to give feedback for next time instant as the output.

(Supplemental Note 2)

The communication apparatus according to Supplemental note 1, wherein

the path splitting unit splits each existing path from previous iteration into two new paths,

one of the two new path is created by appending 1 to the existing path, and

the other one of the two new path is created by appending −1 to the existing path.

(Supplemental Note 3)

The communication apparatus according to Supplemental note 1 or 2, wherein

the path metric update unit obtains the path metric for each of the two path created by the path splitting unit using the path metric of the existing path and associated quantization noise for each new path.

(Supplemental Note 4)

The communication apparatus according to any one of Supplemental notes 1 to 3, wherein

the path metric sort unit sorts the paths created by the path splitting unit according to path metric values obtained from the path metric update unit in an ascending order, and

the path metric sort unit does the sorting in a global fashion.

(Supplemental Note 5)

The communication apparatus according any one of Supplemental notes 1 to 4, wherein

the path pruning unit retains half of the paths created by the path splitting unit based on the results of sorting of the path metric sort unit.

(Supplemental Note 6)

The communication apparatus according to any one of Supplemental notes 1 to 5, wherein

the select path unit selects the path with the lowest path metric at the end of quantization of all samples of input baseband signal.

(Supplemental Note 7)

The communication apparatus according to any one of Supplemental notes 1 to 6, wherein

the feedback selector selects feedback corresponding to paths that are retained by path pruning unit, and

the selection of feedbacks is done using result of sorting from the path metric sort unit.

(Supplemental Note 8)

The communication apparatus according to any one of Supplemental notes 1 to 7, wherein

the computation unit takes in feedback of the paths that survived pruning in previous time instant, and adds it to present sample of baseband input signal to obtain feedback of the paths created by the path splitting unit.

(Supplemental Note 9)

A decoding method of a communication apparatus comprising:

updating a path metric of each path at each iteration;

splitting an existing path into two paths, with one path being formed by appending 1 to the existing path and, the other path being formed by appending −1 to the existing path;

sorting the paths in the ascending order of their path metric values;

choosing L (L is an integer more than 1) paths which have lower path metric values;

selecting a path with lowest path metric among all available paths at the end of all the baseband samples and the selected path serving as the output bit sequence;

selecting the feedback corresponding to the feedback associated with paths selected by path pruning;

processing the selected feedback and the input baseband signal, and to give feedback for next time instant as the output.

(Supplemental Note 10)

The decoding method according to Supplemental note 9, wherein

the splitting comprises splitting each existing path from previous iteration into two new paths,

one of the two new path is created by appending 1 to the existing path, and

the other one of the two new path is created by appending −1 to the existing path.

(Supplemental Note 11)

The decoding method according to Supplemental note 9 or 10, wherein

the updating comprises obtaining the path metric for each of the two path created by the splitting using the path metric of the existing path and associated quantization noise for each new path.

(Supplemental Note 12)

The decoding method according to any one of Supplemental notes 9 to 11, wherein

the sorting comprises sorting the paths created by the path splitting according to path metric values in an ascending order, and

the sorting is done in a global fashion.

(Supplemental Note 13)

The decoding method according to any one of Supplemental notes 9 to 12, wherein

the splitting comprises retaining half of the paths created by the path splitting based on the results of sorting.

(Supplemental Note 14)

The decoding method according to any one of Supplemental notes 9 to 13, wherein

the selecting of paths comprises selecting the path with the lowest path metric at the end of quantization of all samples of input baseband signal.

(Supplemental Note 15)

The decoding method according to any one of Supplemental notes 9 to 14, wherein

the selecting of the feedback comprises selecting feedback corresponding to paths that are retained by the path pruning, and

the selection of feedbacks is done using result of the sorting.

(Supplemental Note 16)

The decoding method according to any one of Supplemental notes 9 to 15, wherein

the processing comprises taking in the feedback of the paths that survived pruning in previous time instant, and adding it to present sample of baseband input signal to obtain feedback of the paths created by the path splitting.

### REFERENCE SIGNS LIST

10 DELTA SIGMA MODULATOR
11 COMPARATOR
12 ADDER
13 ADDER
50 COMMUNICATION APPARATUS
51 PATH METRIC UPDATE UNIT
52 PATH CREATOR
53 PATH METRIC SORT
54 PATH PRUNING
55 SELECT PATH UNIT
56 FEEDBACK SELECTOR
57 COMPUTATION UNIT
70 COMMUNICATION APPARATUS
72 PATH CREATOR
73 PATH METRIC UPDATE UNIT
74 PATH PRUNING
75 PATH METRIC SORT
718 SELECT PATH UNIT
76 FEEDBACK SELECTOR
79 COMPUTATION UNIT
710 COMPUTATION UNIT

What is claimed is:

1-16. (canceled)

17. A communication apparatus comprising:
a path metric update unit configured to update a path metric of each path at each iteration;
a path splitting unit configured to split an existing path into two paths, with one path being formed by appending 1 to the existing path and, the other path being formed by appending −1 to the existing path;
a path metric sort unit configured to sort the paths in the ascending order of their path metric values;
a path pruning unit configured to choose L (L is an integer more than 1) paths which have lower path metric values;
a select path unit configured to select a path with lowest path metric among all available paths at the end of all the baseband samples and the selected path serving as the output bit sequence;
a feedback selector configured to select feedback corresponding to the feedback associated with paths selected by the path pruning unit; and
a computation unit configured to process the feedback from the feedback selector and the input baseband signal, and to give feedback for next time instant as the output.

18. The communication apparatus according to claim 17, wherein
the path splitting unit splits each existing path from previous iteration into two new paths,
one of the two new paths is created by appending 1 to the existing path, and
the other one of the two new paths is created by appending −1 to the existing path.

19. The communication apparatus according to claim 17, wherein
the path metric update unit obtains the path metric for each of the two paths created by the path splitting unit using the path metric of the existing path and associated quantization noise for each new path.

20. The communication apparatus according to claim 17, wherein
the path metric sort unit sorts the paths created by the path splitting unit according to path metric values obtained from the path metric update unit in an ascending order, and
the path metric sort unit does the sorting in a global fashion.

21. The communication apparatus according to claim 17, wherein
the path pruning unit retains half of the paths created by the path splitting unit based on the results of sorting of the path metric sort unit.

22. The communication apparatus according to claim 17, wherein
the select path unit selects the path with the lowest path metric at the end of quantization of all samples of input baseband signal.

23. The communication apparatus according to claim 17, wherein
the feedback selector selects the feedback corresponding to paths that are retained by path pruning unit, and
the selection of feedbacks is done using result of sorting of the path metric sort unit.

24. The communication apparatus according to claim 17, wherein
the computation unit takes in feedback of the paths that survived pruning in previous time instant, and adds it to present sample of baseband input signal to obtain feedback of the paths created by the path splitting unit.

25. A decoding method comprising:
updating a path metric of each path at each iteration;
splitting an existing path into two paths, with one path being formed by appending 1 to the existing path and, the other path being formed by appending −1 to the existing path;
sorting the paths in the ascending order of their path metric values;
choosing L (L is an integer more than 1) paths which have lower path metric values;
selecting a path with lowest path metric among all available paths at the end of all the baseband samples and the selected path serving as the output bit sequence;
selecting the feedback corresponding to the feedback associated with paths selected by path pruning; and
processing the selected feedback and the input baseband signal to give feedback for next time instant as the output.

26. The decoding method according to claim 25, wherein
the splitting comprises splitting each existing path from previous iteration into two new paths,
one of the two new paths is created by appending 1 to the existing path, and
the other one of the two new paths is created by appending −1 to the existing path.

27. The decoding method according to claim 25, wherein
the updating comprises obtaining the path metric for each of the two paths created by the splitting using the path metric of the existing path and associated quantization noise for each new path.

28. The decoding method according to claim 25, wherein
the sorting comprises sorting the paths created by the path splitting according to path metric values in an ascending order, and
the sorting is done in a global fashion.

29. The decoding method according to claim 25, wherein
the splitting comprises retaining half of the paths created by the path splitting based on the results of sorting.

30. The decoding method according to claim 25, wherein
the selecting of paths comprises selecting the path with the lowest path metric at the end of quantization of all samples of input baseband signal.

31. The decoding method according to claim 25, wherein
the selecting of the feedback comprises selecting feedback corresponding to paths that are retained by the path pruning, and
the selection of feedbacks is done using result of the sorting.

32. The decoding method according to claim 25, wherein
the processing comprises taking in the feedback of the paths that survived pruning in previous time instant, and adding it to present sample of baseband input signal to obtain feedback of the paths created by the path splitting.
